(19) United States
(12) Patent Application Publication
(10) Pub. No.: US 2001/0012667 A1
(43) Pub. Date: Aug. 9, 2001

(54) Clustered system and method for formation of integrated circuit devices

(76) Inventors: Yi Ma, Orlando, FL (US); Kurt George Steiner, Orlando, FL (US); Minseok Oh, Orlando, FL (US)

Correspondence Address: Michael B. Fein, Schnader Harrison Segal & Lewis LLP, 1600 Market Street, Suite 3600, Philadelphia, PA, 19103-7286, US

(21) Appl. No.: 09/814,580

(22) Filed: Mar. 22, 2001

Related U.S. Application Data
(62) Division of application No. 09/232,752, filed on Jan. 15, 1999.

(51) Int. Cl. H01L 21/00; H01L 21/64; H01L 21/336

(52) U.S. Cl. 438/287; 29/25.01; 438/906; 438/908

(57) ABSTRACT

A method for forming high quality integrated circuit devices and apparatus therefor. The method includes the steps of forming an oxide layer on a semiconductor material wafer and then depositing a nitride or oxynitride layer over the oxide layer. All steps being taken without exposing the wafer to surrounding atmosphere. The invention also relates to a cluster tool for carrying out the above steps.

### CROSS REFERENCE TO RELATED APPLICATION

This application is a Divisional application from application Ser. No. 09/232,752 filed on Jan. 15, 1999.

### BACKGROUND OF THE INVENTION

1. Field of the Invention

The present invention relates to a method for forming high quality integrated circuit devices. Moreover, the invention also relates to a cluster tool system for forming such high quality integrated circuit devices.

2. Description of the Prior Art

In semiconductor integrated circuit device processing, a first aspect of device fabrication is the cleaning of the wafer substrates before subsequent processing. For example, before silicon dioxide is grown on the surface of a silicon wafer to form a gate oxide layer, the wafer is typically cleaned to remove contaminants, such as particulate contaminants, metallic contamination, and any native oxide that may have formed on the portions of the wafer over which the gate oxide layer is to be grown. It is well known that the cleaning step is especially critical prior to the growth of gate oxide material on silicon wafers. It is also well known to the skilled artisan that the gate oxide is a thin layer of oxide below the gate in a transistor such as a MOSFET.

Typically, after cleaning the silicon wafer surface, a layer of silicon dioxide is grown thereon using conventional techniques such as atmospheric furnace or rapid thermal oxidation (RTO). After the oxide layer is grown, device structures are formed on the silicon wafer using any number of conventional processing techniques.

For example, it is known to deposit a nitride and/or an oxynitride layer over the silicon dioxide layer by, for example, conventional or remote plasma enhanced chemical vapor deposition (PECVD). After formation of the nitride and/or oxynitride layer, it is also known to thereafter deposit a layer of polycrystalline silicon (polysilicon) or conducting metal silicide over the nitride layer. The polysilicon layer may be doped. For example, the polysilicon may be subjected to a phosphorus ion implantation process for n-type doping. However, p-type doping is needed for NMOS devices to improve their performance. Therefore, it is also known to dope the polysilicon layer with boron. In such a case, the previously deposited nitride and/or oxynitride layer blocks boron penetration from the boron doped polysilicon through the oxide gate dielectric layer into the channel region. Such penetration degrades gate oxide reliability and shifts the device threshold voltage.

The above-described process steps typically require moving the device between separate process equipment. Even though the individual process equipment is typically located in a “clean room” environment, the device wafer is still subject to contamination when being moved from process equipment to process equipment.

It is known to use clustered systems for preventing contamination of device wafers during certain process fabrication steps. For example, commonly assigned U.S. Pat. No. 5,814,562 discloses the use of a cluster tool to prevent contamination of the device wafer between a pre-cleaning step and formation of the gate oxide layer by RTO. The patent discloses a novel two-step process for cleaning silicon wafers which is practiced in a multi-chamber processing tool (commonly referred to as a cluster tool). The pre-cleaning steps comprise placing a silicon wafer in an atmosphere that is essentially free of oxygen. Preferably, the wafer is placed in a vacuum. The wafer is then subjected to an etching mixture of HF and methanol. After vapor phase HF etching, the silicon wafer is then subjected to a stream of photo-exited chlorine (Cl₂). This step of the process is referred to as UVCl₂. The patent also discloses that the cleaned silicon wafers may be further processed by transferring the wafer to a second chamber of the cluster tool and then growing on the wafer's surface a layer of silicon dioxide using conventional techniques such as RTO. Thereafter, device structures are formed on the silicon wafers using conventional processing techniques.

U.S. Pat. No. 5,792,261 discloses a plasma enhanced chemical vapor deposition (PECVD) apparatus for forming a silicon film on an LCD substrate which includes a container which is divided into process and upper chambers by a quartz partition plate. The PECVD apparatus is part of a cluster tool which is used to form, for example, transistors. The patent also discloses that the plasma apparatus can be applied to plasma etching, ashing and sputtering apparatuses.

### SUMMARY OF THE INVENTION

In one aspect, an embodiment of the present invention is directed to a process for forming semiconductor integrated circuit devices comprising the steps of: providing a semiconductor material wafer; placing the wafer into a vacuum chamber; and growing an oxide layer thereon to form an oxide gate-dielectric; and moving the wafer into an adjacent chemical vapor deposition vacuum chamber without exposure to surrounding atmosphere and forming a nitride layer or oxynitride layer over the oxide gate-dielectric by chemical vapor deposition.

In another aspect, another embodiment of the invention is directed to a cluster tool which shields the semiconductor material wafer from contamination when transferring the wafer from one vacuum chamber to another. The cluster tool comprises: a central transfer vacuum chamber; an oxidation vacuum chamber connected to the central transfer vacuum chamber for growing a first oxide layer on the semiconductor material wafer; and a chemical vapor deposition vacuum chamber connected to the central transfer vacuum chamber for depositing a nitride or oxynitride layer over the first oxide layer. The cluster tool is arranged so that the semiconductor material wafer may be transferred from the central transfer vacuum chamber to the oxidation vacuum chamber and to the chemical vapor deposition vacuum chamber without exposing the semiconductor material wafer to contamination from the atmosphere outside of the cluster tool.

### BRIEF DESCRIPTION OF THE DRAWINGS

FIG. 1 is a cross-section schematic drawing of a cluster tool according to an embodiment of the present invention.

### DETAILED DESCRIPTION

The invention will be understood more fully from the detailed description given below and from the accompanying drawing of one embodiment of the invention, which however, should not be taken to limit the invention to a specific embodiment, but is for explanation and understanding only.

Throughout the specification “semiconductor material” should be understood to mean any material with semiconductor properties. Preferred semiconductor materials include, for example, silicon, silicon germanium, and gallium arsenic, with silicon being particularly preferred.

An embodiment of the invention comprises first growing an oxide layer on a surface of a semiconductor material wafer. Suitable methods for growing the oxide layer include, for example, atmospheric furnace and rapid thermal oxidation (RTO). Thereafter, a nitride or oxynitride layer is deposited onto the oxide layer by chemical vapor deposition. Suitable chemical vapor deposition processes include, for example, conventional or remote plasma enhanced chemical vapor deposition (PECVD). The steps may be conducted within a vacuum cluster tool which shields the wafer from contamination from the atmosphere outside of the cluster tool during processing.

The embodiment of the invention may also include the above two process steps and additionally comprise a pre-cleaning step carried out within a vacuum chamber which is included in the cluster tool. The preferred pre-cleaning step is a UVCl₂ pre-gate clean step carried out in a vacuum chamber, as disclosed in U.S. Pat. No. 5,814,562.

The embodiment of the invention may also include first growing an oxide layer on a surface of a semiconductor wafer, and thereafter depositing a nitride or oxynitride layer onto the oxide layer, followed by depositing a layer of polycrystalline silicon (polysilicon) over the nitride or oxynitride layer, preferably by a low pressure chemical vapor deposition process (LPCVD), or by a rapid thermal chemical vapor deposition process (RTCVD).

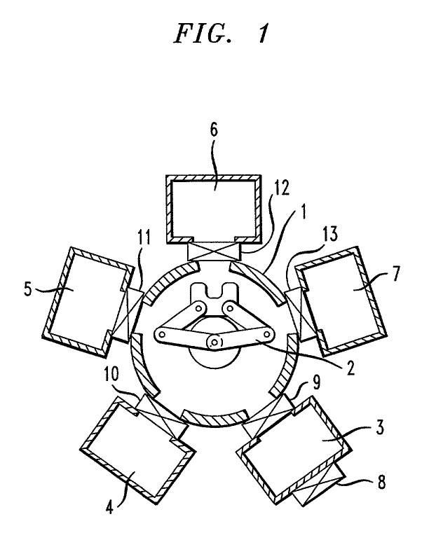

Turning now to FIG. 1, there is shown a schematic cross-section of one cluster tool according to an embodiment of the present invention. The cluster tool includes central transfer vacuum chamber 1. Within central transfer vacuum chamber I is a suitable transferring means 2 for transferring a semiconductor material wafer to and from the various chambers attached to the central transfer vacuum chamber 1. Suitable means for transferring the wafer are known to those skilled in the art and include, for example, a transfer arm, a robot and the like. The cluster tool additionally includes an input/output vacuum chamber 3 which may be connected to a vacuum source. The cluster tool additionally includes pre-gate clean vacuum chamber 4 for carrying out a pre-cleaning step such as the UVCl₂, process described above. Also shown as part of the cluster tool is an oxidation vacuum chamber 5 for growing a gate oxide layer on the wafer. Suitable oxidation vacuum chambers include, for example, atmospheric furnace and RTO, with RTO vacuum chambers being particularly preferred. PECVD vacuum chamber 6 for depositing a nitride and/or oxynitride layer (i.e., a dielectric) on the oxide layer is also shown. Also shown is a chemical vapor deposition vacuum chamber 7 for depositing a polysilicon layer over the nitride or oxynitride layer. Suitable chemical vapor deposition vacuum chambers include, for example, LPCVD and RTCVD vacuum chambers. The cluster tool also includes sealable gate valves 9-13 which serve to connect the various chambers to the central transfer chamber 1. Other suitable means for connecting the chambers to the central transfer chamber may also be used. Also shown is sealable gate valve 8 which provides a means for placing and removing substrates into input/output chamber 3.

In a preferred embodiment, each vacuum chamber is provided with its own vacuum port (not shown) which is preferably located on a bottom surface of the vacuum chamber. Each chamber can then individually be evacuated to a desired vacuum level by a vacuum pump (not shown) provided to each port. Moreover, any desirable gas may be introduced into each vacuum chamber by providing gas inlet ports (not shown) to each vacuum chamber. In a preferred embodiment, the gas inlet ports are provided at a top surface of each furnace and each inlet port may be provided with a “shower-head” type nozzle to provide for uniform gas injection, which will result a more uniform film being formed on the wafer. Finally, in a preferred embodiment, each vacuum chamber may be provided with a means for holding the wafer (e.g., an electrostatic chuck) (not shown) within the chamber while the wafer is being processed. Preferably, the means for holding the wafer is located at about the center of the vacuum chamber and is capable of rotating 360° to allow for more uniform processing of the wafer.

According to the embodiment of the invention, a semiconductor material wafer may be placed within input/output chamber 3 and gate valve 8 closed. Input/output chamber 3 and central transfer chamber 1 can then each be evacuated, preferably by a vacuum pump attached to each chamber. A suitable vacuum level is about 1×10⁻⁶ Torr. After evacuating input/output chamber 3 and central transfer chamber 1, gate valve 9 may be opened and transferring means 2 used to remove the wafer from input/output chamber 3 and place the wafer into evacuated oxidation vacuum chamber 5. Preferably, oxidation vacuum chamber 5 is evacuated to a vacuum level of about 1×10⁻⁶ Torr by a vacuum pump attached to the chamber. After placing the wafer into oxidation vacuum chamber 5, gate valve 11 is closed. Thereafter, oxidation vacuum chamber 5 is backfilled with an oxygen containing gas and an oxide layer, for example, silicon dioxide, is grown on the wafer, preferably by RTO. A preferred oxide layer thickness is from about 5 to 10 Angstrom. After forming the oxide layer on the wafer surface, oxidation vacuum chamber 5 can be evacuated. After removing substantially all of the oxygen from oxidation vacuum chamber 5, gate valve 11 is opened and transferring means 2 is inserted into oxidation vacuum chamber 5 and the wafer is removed from the chamber.

Thereafter, the wafer is inserted into evacuated PECVD vacuum chamber 6 and gate valve 12 is closed. PECVD vacuum chamber 6 is preferably evacuated to a vacuum level of about 1×10⁻⁶ Torr by a vacuum pump attached to the chamber. A nitride layer or oxynitride layer is then deposited over the grown oxide layer by PECVD techniques, such as conventional or remote PECVD. A preferred nitride or oxynitride layer thickness is from about 5 to 10 Angstrom. After depositing the nitride layer or oxynitride layer, gate valve 12 is opened and transferring means 2 is inserted into PECVD vacuum chamber 6 and the wafer is removed from the chamber. Thereafter, the transferring means 2 transfers the wafer to input/output chamber 3, gate valve 9 is closed and the wafer is removed from the cluster tool.

In another embodiment, a semiconductor material wafer is inserted into input/output vacuum chamber 3 and gate valve 8 is closed. Input/output vacuum chamber 3 and central transfer chamber 1 are evacuated, preferably to a vacuum level of about 1×10⁻⁶ Torr. Thereafter, gate valve 9 is opened and transfer means 2 is inserted into input/output vacuum chamber 3, the wafer is removed from the chamber and inserted into pre-gate clean vacuum chamber 4, which is also evacuated, preferably to a vacuum level of about 1×10⁻⁶ Torr, and preferably by a vacuum pump attached to the chamber. After inserting the wafer into the pre-gate clean vacuum chamber 4, gate valve 10 is closed and the surface of the wafer is cleaned, preferably by the technique described in U.S. Pat. No. 5,814,562, although other techniques may be used.

After cleaning the surface of the wafer, an oxide layer may be grown on the wafer and a nitride layer or oxynitride layer deposited over the oxide layer, as discussed above.

In another embodiment of the present invention, an oxide layer may be grown on a semiconductor material wafer and a nitride or oxynitride layer deposited over the oxide layer, as described above. Thereafter, transferring means 2 transfers the wafer to evacuated chemical vapor deposition vacuum chamber 7 and gate valve 13 is closed. Chemical vapor deposition vacuum chamber 7 is preferably evacuated to a vacuum level of about 1×10⁻⁶ Torr by a vacuum pump attached to the chamber. A polysilicon layer is then deposited over the nitride or oxynitride layer by CVD techniques, such as LPCVD or RTCVD. Gate valve 13 is then opened and the wafer removed from chamber 7 by transferring means 2. Gate valve 9 may then be opened and the wafer placed in input/output chamber 3 by the transferring means 2. Gate valve 9 may then be closed and gate valve 8 opened and the wafer removed.

In another embodiment, a semiconductor material wafer may first be cleaned, an oxide layer grown thereon, a nitride or oxynitride layer deposited over the oxide layer, and a polysilicon layer deposited over the nitride or oxynitride layer, all steps being described above.

As will now be appreciated by those skilled in the art, the above described invention provides a unique method for fabricating a semiconductor integrated circuit device without subjecting the device to contaminants between fabrication steps. Particularly preferred devices include, for example, metal oxide semiconductor field effect transistor (MOSFET) and dynamic random access memory (DRAM) devices. Further, the invention also includes the unique combination of process chambers combined into a cluster tool.

While the invention has been described with specificity, additional advantages and modifications will readily occur to those skilled in the art. Therefore, the invention in its broader aspects is not limited to the specific details shown and described herein. Accordingly, various modifications may be made without departing from the spirit or scope of the general inventive concept as defined by the appended claims and their equivalents.

What is claimed is:

1. A method for forming an integrated circuit device comprising:
placing a semiconductor material wafer into a vacuum chamber and growing an oxide layer thereon to form an oxide gate-dielectric; and
moving the wafer into an adjacent chemical vapor deposition vacuum chamber without exposure to surrounding atmosphere and forming a nitride or oxynitride layer over the oxide gate-dielectric by a chemical vapor deposition process.

2. The method of claim 1, wherein the semiconductor material wafer comprises a material selected from the group consisting of silicon, silicon germanium, and gallium arsenic.

3. The method of claim 2, wherein the semiconductor material wafer comprises silicon.

4. The method of claim 1, further including the step of pre-cleaning the wafer in a UVCl₂ pre-gate clean vacuum chamber and then placing the wafer into the first vacuum chamber without exposing the wafer to surrounding atmosphere.

5. The method of claim 4, further including the step of forming a polycrystalline silicon layer over the nitride or oxynitride layer in a polycrystalline silicon deposition vacuum chamber without exposing the wafer to surrounding atmosphere.

6. The method of claim 1, wherein the chemical vapor deposition vacuum chamber is selected from a plasma enhanced chemical vapor deposition vacuum chamber and a rapid thermal chemical vapor deposition vacuum chamber.

7. The method of claim 6, wherein the chemical vapor deposition chamber is a plasma enhanced chemical vapor deposition chamber.
